(19) United States
(12) Patent Application Publication
(10) Pub. No.: US 2009/0315644 A1
(43) Pub. Date: Dec. 24, 2009

(54) HIGH-Q DISK NANO RESONATOR DEVICE AND METHOD OF FABRICATING THE SAME

(75) Inventors: Sabrina C. Sheedy, Burnsville, MN (US); James F. Detry, Plymouth, MN (US); Andrzej Peczalski, Eden Prairie, MN (US); Chunbo Zhang, Plymouth, MN (US); Steven J. Eickhoff, Plymouth, MN (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignee: Honeywell International Inc.

(21) Appl. No.: 12/142,487

(22) Filed: Jun. 19, 2008

(51) Int. Cl. H03H 9/00; H01L 21/00

(52) U.S. Cl. 333/186; 438/49; 438/50

(57) ABSTRACT

A nanoresonator device with high quality factor and method for fabricating the same is disclosed herein. The nanoresonator device generally includes an input electrode, an output electrode, a nanoresonator anchored at its motionless nodal points of its resonance modes by support beam(s) and/or anchor. The nanoresonator device can be fabricated on various wafers including a silicon on insulator (SOI) wafer, which includes an insulating layer and a heavily doped silicon layer. The nano structures with high quality factor can be patterned on a film utilizing nano fabrication tools and the patterned structures can be utilized as a mask to form permanent nano structures on the silicon layer by reactive ion etching (RIE). The insulating layer can be removed to form the anchor beams and a cavity by wet etching utilizing an etching solution.

### TECHNICAL FIELD

Embodiments are generally related to micromechanical resonators. Embodiments are also related to nanoresonators. Embodiments are additionally related to methods for fabricating nanoresonators.

### BACKGROUND OF THE INVENTION

Microelectromechanical systems (MEMS) include mechanical and electrical components having dimensions in the order of microns or smaller. MEMS structures can be utilized in numerous applications including microsensors and microresonators. Micromechanical resonators have been widely studied for RF signal processing (e.g., oscillator, filter, and mechanical circuit) and for high-precision measurements (e.g., mass/chemical, force, position, and frequency). Vibrating RF MEMS resonators are widely studied for frequency selection in communication sub-systems because of their high quality factor (Q) and excellent stability against thermal variations and aging. Vibrating RF MEMS resonators can replace off-chip components and improve the system size, cost and power consumption. Such resonators in sizes of ten-micron have achieved very high quality factors for example, Q up to 10,000 to 100,000 in air at MHz-GHz frequencies, and are envisioned to replace the high-Q components in existing wireless systems.

Nanoscale structures are becoming increasingly important because they provide the basis for devices with dramatically reduced power and mass, while simultaneously possessing enhanced capabilities. Nanoscale mechanical structures hold the potential to enable the fabrication of high-Q mechanical resonators with high mechanical responsivity over a wide dynamic range. Such devices can form very low-loss, low-phase-noise oscillators for filters, local oscillators, and other signal processing applications. High-Q resonators are critical components in communications and radar systems, as well as in MEMS-based sensors such as a micro-gyroscope. The combination of high-Q with small force constants enabled by nanoscale resonators can also produce resonators with exceptional force sensitivity.

The resonator scaling from micro to nano size can provide significant advantages of multiple times or order of magnitude higher sensitivity, higher frequency, lower power, and higher density. The problem associated with the development of such nanoresonator (ex., nanowire resonator) is due to the reliable low-loss structure and fabrication. Also, such nanoresonator often results in large air damping losses and anchor losses that affects Q. In addition to anchor losses, air-damping forces create more losses when operating in atmosphere and hence further reduction in Q. Low-loss microresonator structures have been demonstrated using MEMS processes. However, it is not easy to fabricate a low-loss structure in 1 um or sub micron size utilizing prior art fabrication process because of the smaller size and multiple sub-micron-alignment needs.

Based on the foregoing it is believed that a need exists for an improved low-loss and high-Q nanoresonator device. A need also exists for an improved method for fabricating the high-Q nanoresonator device as described in greater detail herein.

### BRIEF SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the present invention to provide for an improved high-Q nanoresonator device.

It is another aspect of the present invention to provide for an improved method for fabricating high-Q nanoresonator device.

The aforementioned aspects and other objectives and advantages can now be achieved as described herein. A nanoresonator device with high quality factor and method for fabricating the same is disclosed herein. The nanoresonator device generally includes an input electrode, an output electrode, a nanoresonator anchored at its motionless nodal points of its resonance modes by an anchor beam. The nanoresonator device can be fabricated on a wafer, such as a silicon insulator (SOI) wafer, which includes an insulating layer and a conductive layer formed on the insulating layer. The conductive layer can be comprised of several conductive materials to include heavily doped silicon layer. The nanoresonator can also be fabricated on other wafers with structure similar to SOI wafer, such as a wafer with top electrically-conductive layer above a middle insulation layer on the surface of a substrate. The nano structures with high quality factor can be patterned on a film utilizing nano fabrication tools and the patterned structures can be utilized as a mask to form permanent nano structures on the conductive layer of the wafer by reactive ion etching (RIE). The insulating layer can be removed to form the anchor beam and a cavity under the nano structures by wet etching utilizing an etching solution.

The nano structure can be patterned in a polymethylmethacrylate (PMMA) film or a ZEP film utilizing an electron beam lithography process. The nanoresonator comprises a disk structure or a ring structure with high quality factor and a diameter of sub micron or micron size. The high-Q nano structures can be fabricated utilizing nano fabrication tools such as E-beam lithography or focused ion beam (FIB) etching on conductive and insulating layers associated with a wafer. Anchor beams can provide electrical contact to the nanoresonator. The nanoresonator can be electrostatically driven into its radial contour resonant modes by the input electrodes. The small radial expansion and contraction amplitudes in the resonant modes greatly reduce the air damping and the motionless anchor beams minimize elastic wave radiation. Such nanoresonator device can provide significant advantages of multiple times or order of magnitude of higher sensitivity, higher frequency, lower power, and higher density.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 illustrates a top view of a high-Q disk nanoresonator device, in accordance with a preferred embodiment;

FIG. 2 illustrates a cross sectional view of the high-Q disk nanoresonator device, in accordance with a preferred embodiment;

FIGS. 3a and 3b show photographs of SEM device views after E-beam lithography and top layer pattern formation by RIE etch, which can be implemented in accordance with a preferred embodiment, (a) a disk device (b) a ring device; and

FIG. 4 illustrates a high level flow chart of operations illustrating logical operational steps of a method for fabricating the high-Q disk nanoresonator device, in accordance with a preferred embodiment.

FIG. 5 shows a photograph of a disk device after atomic layer deposition of TiO2.

### DETAILED DESCRIPTION

The particular values and configurations discussed in these non-limiting examples can be varied and are cited merely to illustrate at least one embodiment and are not intended to limit the scope thereof.

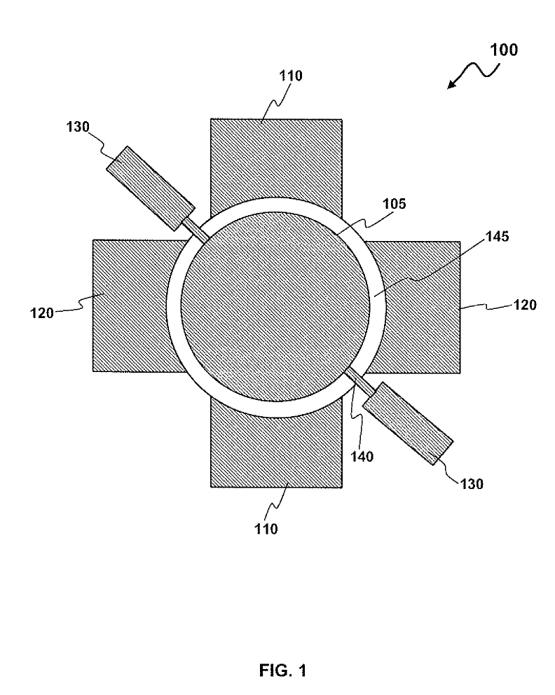

Referring to the drawings and in particular to FIG. 1, there is depicted a top view of a high-Q disk nanoresonator device 100, in accordance with a preferred embodiment. The nano disk resonator device 100 generally includes an input electrode 110 and an output electrode 120. Electrodes 110 and 120 can be symmetrical and interchangeable. The device 100 can further include a resonator disk 105 anchored at its motionless nodal points of its resonance modes by an anchor 130 supported by a support beam 140. The nano features for the high-Q nano disk resonator device 100 can be incorporated by the resonator disk 105 having a diameter of approximately 100-5000 nm and a thickness of approximately 200-400 nm. An air gap 145 spacing the input electrode 110 and the output electrode 120 from the resonator disk 105 can be formed with an approximate gap of 10 nm to 300 nm and the support beam 140 with width of 50-200 nm. These dimensions are described for purposes of clarity and specificity; however, they should not be interpreted in any limiting way. Other dimensions are possible. However, it will be apparent to those of skill in the art that other dimensions can be utilized as desired without departing from the scope of the invention.

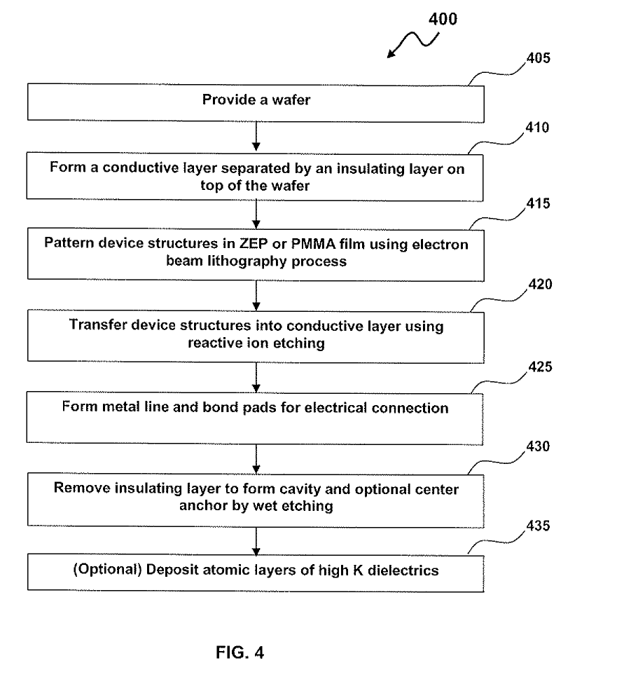

The resonator disk 105 can be electrostatically driven into its radial contour resonant modes by the input electrode 110. The quality factor Q can be improved by anchoring the resonator disk 105 at the motionless nodal points of its resonance modes, such as the connection points of anchor beam 140. The small radial expansion and contraction amplitudes (e.g., ˜nm magnitude) in the resonance modes greatly reduce the air damping, while the motionless anchor points minimize elastic wave radiation. The geometry of the associated parameters for incorporating nano features to the high-Q nano disk resonator device 100 can be obtained by a fabrication process 400 as illustrated in FIG. 4.

The mechanical design of the high-Q disk nano resonator device 100 includes a finite element modeling (FEM) simulation to identify the resonance frequency of the nano structure such as the resonator disk 105 and to extract the equivalent mass and effective stiffness of the structure from the kinetic energy integration. The resonance frequency of the nano disk/ring structures can be given by a simplified equation (ref [1-2]):

$${f}_{o} = \frac{α}{2 π {R}_{out}} \sqrt{\frac{E}{ρ ( 1 - {σ}^{2} )}}$$

Where ρ, σ and E are the density, Poisson ratio, and young's modulus, respectively. α is a parameter that depends on the radius and resonator geometry. Rout is the outer radius of the disk/ring.

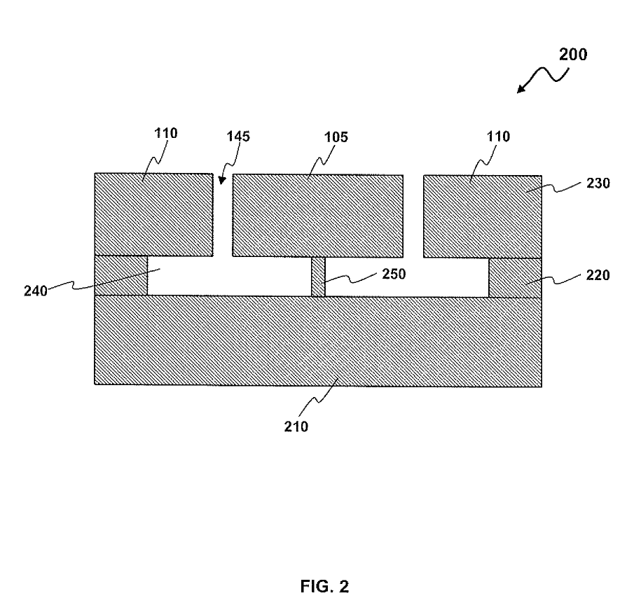

FIG. 2 illustrates a cross sectional view of the high-Q disk nanoresonator device 200, in accordance with a preferred embodiment. The high-Q nano disk resonator device 100 can be fabricated utilizing the fabrication process 400 as depicted in FIG. 4. The fabrication process 400 can utilize nano fabrication tools such as for example electron beam lithography or focused ion beam (FIB) etching and a silicon on insulator (SOI) substrate 210. The device 100 can includes substrate 210, an insulating layer 220 and a conductive layer 230. The insulating layer 220 can be formed on the substrate 210. The substrate 210 can be configured from a material such as, for example, a silicon semiconductor substrate. Wafers with other materials of substrate, insulation layer, and conductive layer can also be used.

The insulating layer 220 described herein can be formed typically utilizing a silicon nitride (Si₃N₄) film or a silicon oxide (SiO₂) film depending on fabrication method. The insulating layer 220 includes a cavity 240 and an optional center anchor 250 can also be formed therein. The center anchor 250 can be removed so that the resonator 105 is only suspended through support beam 140. The input electrode 110 for high-frequency signal input can be formed on the conductive silicon layer 230 on one side of the cavity 240, and the output electrode 120 for high-frequency signal output can be formed on the silicon layer 230 similarly. The resonator disk 105 can be formed above the center anchor 250 enclosed by the input electrode 110 and the output electrode 120 with the gap 145 therebetween. The optional SiO₂ center anchor 250 allows more flexibility for later development and the resonator disk 105 may be more stable with the center anchor 250.

The air gap 145 spacing the input electrode 110 and the output electrode 120 from the resonator disk 105 can be formed to a thickness of 10 nm to 300 nm. A voltage of a predetermined frequency can be applied to the input electrode 110 and the resonator disk 105 supported by the support beam 140 resonates at a specific resonance frequency. This consequently varies capacitance of a capacitor ascribable to the air gap 145 which spaces the resonator disk 105 and the output electrode 120 and a signal of the capacitance is output from the output electrode 120. A high-frequency filter composed of this type of nano or micro resonator 100 can realize a higher Quality-factor.

The resonator device 100 can be measured utilizing a direct measurement method and a mixing measurement method. The direct measurement method can tolerate up to −62 dB of transmission loss caused by the impedance mismatch. In mixing measurement method, the device 100 can be driven by off-resonance signals for example, an RF signal and a carrier signal which mix through a capacitive transducer nonlinearly to generate a driving force at the difference frequency. If the difference frequency is equal to the resonance frequency, then the resonator device 100 can be driven into vibration. Because none of the input signals is at the resonance frequency, no direct feed through is expected at this frequency, and output currents at this frequency are much less affected by large motional impedance. The mixing technique allows measurement of a substantially cleaner resonance spectrum by suppressing feed through, thus providing more accurate data to characterize the resonator device 100, especially for devices to operate at high frequencies.

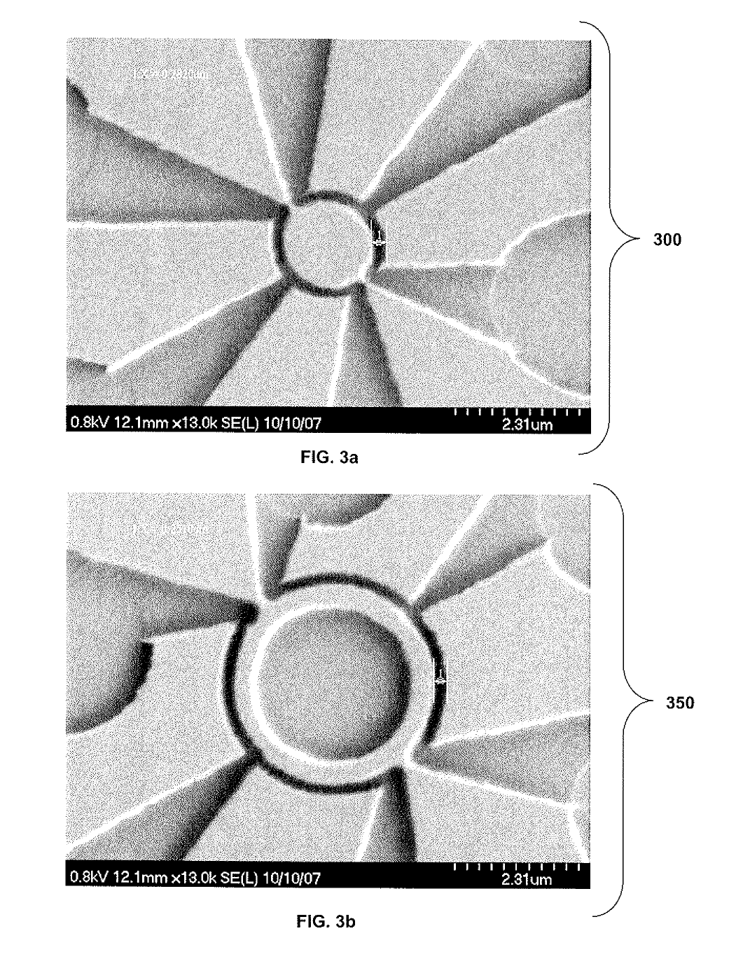

FIG. 3 shows SEM photographs 300 and 350 of a disk pattern and a ring pattern formed through electron beam lithography and RIE etch, respectively, in accordance with a preferred embodiment. Electron beam lithography is the practice of scanning a beam of electrons in a patterned fashion across a surface covered with a resist film. For example, in electron beam lithography, a substrate configured from a material such as, for example, silicon oxide, silicon, glass, or quartz coated with a metal such as iron or chromium or the oxides, nitrides, and salts of these metals can be coated with a polymer resist material. The resist is exposed to a rastering or moving electron beam in sufficient dosage during patterning, to change the solubility of the resist polymer to a particular solvent in the areas where the electron beam has interacted with the resist. The solvent can be utilized to dissolve away the parts of the resist that are soluble after exposure, while the parts that are not soluble after exposure remain on the substrate which forms electron-beam pattern. The resulting pattern is used as a mask for forming a more permanent pattern on the substrate using a technique such as plating, chemical etching, ion etching, ion-implantation, or photolithography. The primary advantage of electron beam lithography is that it beat the diffraction limit of optical photolithography and makes patterns in a nanometer regime. Such E-beam lithography can be utilized for patterning the nano structures to the silicon layer 230. An alternative approach is focused ion beam (FIB) etch or deposition. FIB uses nanometer size ion beam (usually Ga ion) to pattern a surface.

FIG. 4 illustrates a high level flow chart of operations illustrating logical operational steps of a method 400 for fabricating the high-Q disk nanoresonator device 100, in accordance with a preferred embodiment. Again, as a reminder, in FIGS. 1-5 identical parts or elements are generally indicated by identical reference numerals. A wafer can be provided, as depicted at block 405. The wafer can include an insulating layer 220 such as a SiO₂ film formed on a SOI substrate 210. When used, a silicon layer 230 can be doped heavily to make it conductive. Conductive layer separated by an insulating layer is formed on top of the wafer, as depicted at block 410. Thereafter, as illustrated at block 415, micro and nano device structures such as the resonator disk 105, the input electrode 110 and the output electrode 120 can be patterned in a PMMA or ZEP film utilizing E-beam lithography (or FIB) process as illustrated in FIG. 3. The patterned structures can be utilized as a mask for forming a more permanent pattern into the silicon layer 230 using RIE. The device structures are then transferred into the conductive layer using reactive ion etching, as depicted at block 420.

Next, the metal line and bond pads can be formed for electrical connection and can be connected to the electrodes 110 and 120, as shown at block 425. The insulating layer 220 can be removed to form optional center anchor 250 and cavity 240 by wet etching, as depicted at block 430. Etching agents for the insulating layer, such as BHF (buffered hydrogen fluoride), can be utilized to wet etch insulating layer 220 by totally removing the insulating layer 220 in the bottom of the resonator disk 105 or forming the bottom center anchor 250. The resonator disk 105 can be formed on the center anchor 250 between the input electrode 110 and the output electrode 120, which forms the gap 145 therebetween. Step 430 can complete the process, but multi atomic layers of high K dielectrics such as TiO₂ (titanium dioxide) can be optionally deposited onto the device, as illustrated at block 435, to reduce the motional resistance.

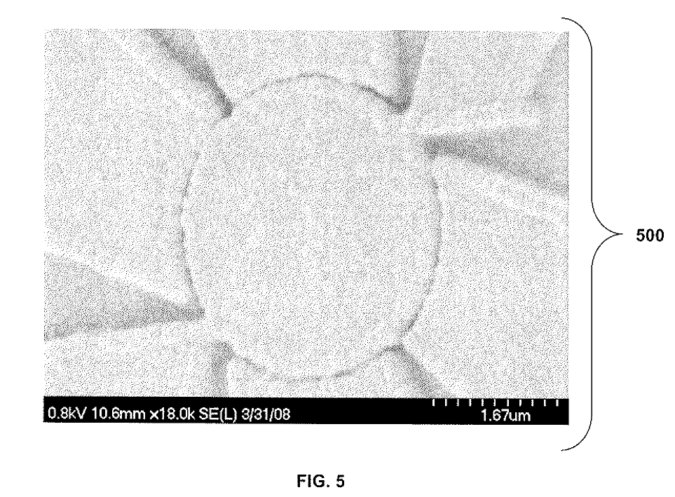

A device picture after atomic layer deposition of TiO2 is shown in FIG. 5, in which the TiO2 does not fully fill the gap. The gap filling can be chosen to be completely filled or partially filled. In the case of partial filling, it is preferred to have a narrow unfilled gap. The nanoresonator disk 105 can be electrostatically driven into its radial contour resonant modes by the input electrodes 110. The small radial expansion and contraction amplitudes in the resonant modes greatly reduce the air damping and the motionless anchor beam 130 minimizes elastic wave radiation. Such nano resonator device 100 can provide significant advantages of multiple times or order of magnitude of higher sensitivity, higher frequency, lower power, and higher density.

It will be appreciated that variations of the above-disclosed and other features and functions, or alternatives thereof, may be desirably combined into many other different systems or applications. Also that various presently unforeseen or unanticipated alternatives, modifications, variations or improvements therein may be subsequently made by those skilled in the art which are also intended to be encompassed by the following claims.

What is claimed is:

1. A method for fabricating a high-Q disk nanoresonator device, comprising:
forming an insulating layer between a substrate and a conductive layer, said conductive layer and insulting layer having a cavity etched therein;
patterning a plurality of high quality factor device structures including an input electrode, an output electrode and a nanoresonator on a film utilizing at least one nano fabrication tool and transferring said plurality of device structures onto said conductive layer by RIE etching processing and forming support beams; and
removing said insulating layer to form anchor beams and said cavity by wet etching utilizing an etching solution.

2. The method of claim 1 wherein said plurality of device structures comprises at least one of a microstructure and a nanostructure.

3. The method of claim 1 further comprising anchoring said nanoresonator on said support beams at motionless nodal points of resonance modes of said nanoresonator.

4. The method of claim 1 wherein said substrate and layers are comprised of SOI.

5. The method of claim 1 wherein said at least one nano fabrication tool comprises at least one of electron beam lithography and focused ion beam (FIB) patterning.

6. The method of claim 1 further comprising providing electrical contact to said nanoresonator by said support beam(s) wherein said nanoresonator is electrostatically driven into its resonant modes by said input electrode.

7. The method of claim 1 wherein said resonator comprises at least one of a ring shape and a disk shape.

8. The method of claim 1 wherein said film comprises at least one of a PMMA (polymethylmethacrylate) and ZEP film.

9. The method of claim 1 further comprising the step of forming a central anchor within said cavity between said substrate and said conductive layer, wherein said central anchor provides flexibility and stability to said nanoresonator.

10. A method for fabricating a high-Q disk nanoresonator device, comprising:
forming an insulating layer having a cavity etched therein on a substrate including a conductive layer in association with said substrate;
patterning a plurality of device structures with high quality factor on a film utilizing at least one nano fabrication tool and transferring said plurality of device structures on said conductive layer by RIE etching process and forming support beams wherein said plurality of device structures comprises an input electrode, an output electrode and a nanoresonator;
providing electrical contact to said nanoresonator by at least one support beam wherein said nanoresonator is electrostatically driven into radial contour resonant modes by said input electrode;
forming a metal line and a plurality of bond pads on said nanoresonator; and
removing said insulating layer to form anchor beams and said cavity by wet etching utilizing an etching solution.

11. The method of claim 10 wherein said plurality of device structures comprises at least one of a microstructure and a nanostructure.

12. The method of claim 10 further comprising anchoring said nanoresonator on at least one of said support beams at motionless nodal points of resonance modes of said nanoresonator.

13. The method of claim 10 wherein said at least one nano fabrication tool comprises at least one of electron beam lithography and focused ion beam (FIB) patterning.

14. The method of claim 10 wherein said surface of the nanoresonator is coated with functional material layer for at least one of selective gas and selective bio sensing.

15. The method of claim 10 further comprising the step of depositing high K dielectrics as a complete or partial filler within electrode gaps associated with the nanoresonator for reducing motional resistance, wherein said high K dielectric can include titanium oxide.

16. The method of claim 10 wherein said film comprises a PMMA (polymethylmethacrylate) and ZEP film.

17. The method of claim 10 wherein said etching solution comprises a BHF solution (buffered hydrogen fluoride).

18. A high-Q disk nanoresonator device, comprising:
a substrate including an insulating layer formed thereon and further including a conductive layer formed on the insulating layer, the conductive layer having a cavity etched through the conductive layer into the insulating layer therein;
a plurality of high quality factor device structures including an input electrode, an output electrode and a nanoresonator patterned on the conductive layer; and
at least one anchor providing at least one of flexibility, stability, and electrical connection to said nanoresonator; and
a plurality of bond pads formed on at least one of the input electrode, output electrode and nanoresonator by at least one of liftoff and wet etching processing.

19. The high-Q resonator device of claim 18 wherein said plurality of device structures comprises at least one microstructure and/or at least one nanostructure.

20. The high-Q resonator device of claim 18 further comprising electrical contact to said nanoresonator provided by at least one anchor beam, wherein said nanoresonator is electrostatically driven into its resonant modes by said input electrode.
